(19) United States
(12) Patent Application Publication
(10) Pub. No.: US 2011/0095315 A1
(43) Pub. Date: Apr. 28, 2011

(54) PACKAGE SUBSTRATE FOR OPTICAL ELEMENT AND METHOD OF MANUFACTURING THE SAME

(76) Inventors: Ji Hyun PARK, Seoul (KR); Seog Moon Choi, Seoul (KR); Tae Hoon Kim, Seoul (KR); Sang Hyun Shin, Gyunggi-do (KR); Tae Hyun Kim, Seoul (KR)

(21) Appl. No.: 12/632,598

(22) Filed: Dec. 7, 2009

(30) Foreign Application Priority Data
Oct. 26, 2009 (KR) 10-2009-0101765

(51) Int. Cl. H01L 33/00

(52) U.S. Cl. 257/98; 438/27; 257/E33.059; 257/E33.061; 257/E33.066

(57) ABSTRACT

Disclosed herein is a package substrate for optical elements, including: a conductive substrate including an insulation layer formed thereon; a circuit layer which is formed on the conductive substrate 11 and has a cavity space therein; electrode pads which are formed on the conductive substrate and which are spaced apart from the circuit layer by predetermined intervals such that trenches are formed between the circuit layer and the electrode pads; an optical element which is mounted in the cavity space of the circuit layer and which is electrically connected with the electrode pads; and a fluorescent resin layer which is formed on the circuit layer and the optical element to allow the optical element to uniformly emit light. The package substrate is advantageous in that uniform white light can be realized.

### CROSS REFERENCE TO RELATED APPLICATION

This application claims the benefit of Korean Patent Application No. 10-2009-0101765, filed Oct. 26, 2009, entitled “Package Substrate For Optical Element and Manufacturing Method Thereof”, which is hereby incorporated by reference in its entirety into this application.

### BACKGROUND OF THE INVENTION

1. Technical Field

The present invention relates to a package substrate for optical elements, and a method of manufacturing the same.

2. Description of the Related Art

Recently, since light emitting diodes (LEDs) are environment-friendly and exhibit energy consumption reduction effects such as low power consumption, high efficiency, long operating life and the like, compared to conventional optical elements such as incandescent lamps, fluorescent lamps and the like, the demand for LEDs has continuously increased, and thus LEDs are playing a leading part in the general illumination market.

In order to realize white light at the time of manufacturing an LED, an RGB chip is used or a blue LED chip is coated with a red, green or yellow fluorescent substance. In this case, the uniformity of white light is changed according to methods of applying the fluorescent substance.

Conventionally, in order to realize white light, a blue LED chip is mounted in a pre mold cup type cavity, and then a fluorescent substance is dispensed to the mounted blue LED chip.

In this case, it is difficult to realize uniform white light because an optical path length changes according to the shape of a pre mold cup in which the LED is mounted or the shape of a resin layer applied on the LED.

Therefore, it is required to develop a new type package substrate for optical elements, which can improve the light efficiency and optical properties of an optical element by realizing a package structure in which white light is easily and uniformly applied onto the optical element.

### SUMMARY OF THE INVENTION

Accordingly, the present invention has been made to solve the above conventional problems, and the present invention provides a package substrate for optical elements, by which a resin material including a fluorescent substance can be easily applied on an optical element.

Further, the present invention provides a package substrate for optical elements, which can realize uniform white light by decreasing the difference in length of an optical path through which the light emitted from an optical element penetrates a fluorescent substance.

Furthermore, the present invention provides a package substrate for optical elements, which have excellent radiation performance and which can improve light efficiency by increasing the reflexibility of the light emitted from an optical element.

An aspect of the present invention provides a package substrate for optical elements, including: a conductive substrate including an insulation layer formed thereon; a circuit layer which is formed on the conductive substrate 11 and has a cavity space therein; electrode pads which are formed on the conductive substrate and which are spaced apart from the circuit layer by predetermined intervals such that trenches are formed between the circuit layer and the electrode pads; an optical element which is mounted in the cavity space of the circuit layer and which is electrically connected with the electrode pads; and a fluorescent resin layer which is formed on the circuit layer and the optical element to allow the optical element to uniformly emit light and which is formed by filling the cavity space mounted with the optical element with a resin material containing a fluorescent substance.

The package substrate for optical elements may further include a lens molded on the fluorescent resin layer in order to hold the optical element and to protect the optical element and a wire bonding region.

The conductive substrate may be any one selected from among an aluminum (Al) substrate, an aluminum alloy (Al alloy) substrate, a magnesium (Mg) substrate, a magnesium alloy (Mg alloy) substrate, a titanium (Ti) substrate, and a titanium alloy (Ti alloy) substrate. The conductive substrate may have a thickness of 0.1 mm or more.

The circuit layer may include: a lower part on which the optical element is placed; and side wall which are spaced apart from the optical element by predetermined intervals and which are integrated with the lower part.

The top surface of the optical element placed on the lower part of the circuit layer may be flush with the top surfaces of the side wall thereof.

The circuit layer may be made of any one selected from among gold (Au), aluminum (Al) and copper (Cu).

The optical element may include first and second terminals formed on a top surface thereof, the electrode pads may include a first electrode pad electrically connected with the first terminal by wire bonding and a second electrode pad electrically connected with the second terminal by wire bonding, and opposite polar signals may be applied to the first and second terminals, respectively.

The optical element may include a first terminal formed on a top surface thereof and a second terminal formed on a bottom surface thereof, the electrode pads may include a first electrode pad electrically connected with the first terminal by wire bonding and a second electrode pad electrically connected with the second terminal by metal-bonding with the circuit layer, and opposite polar signals may be applied to the first and second terminals, respectively. The second electrode pad may be integrated with the circuit layer.

The optical element may be a light emitting diode (LED).

The lower part and side wall of the circuit layer may be inserted in the conductive substrate.

The circuit layer may further include upper parts integrated with the side wall on the insulation layer.

Another aspect of the present invention provides a method of manufacturing a package substrate for optical elements, including: providing a conductive substrate including an insulation layer formed thereon; forming a circuit layer and electrode pads on the conductive substrate using a plating process; forming a cavity space in the circuit layer including a lower part and a side wall; and mounting an optical element in the cavity space and then applying a fluorescent resin layer thereon.

In the method, the providing of the conductive substrate may include: providing the conductive substrate; and forming an insulation layer on the conductive substrate.

The method may further include: forming a cavity space in the conductive substrate after the providing of the conductive substrate.

In the method, the mounting of the optical element may include: placing the optical element on a lower part of the circuit layer; electrically connecting the optical element; and filling the cavity space with a resin material including a fluorescent substance to form a dome-shaped fluorescent resin layer on the optical element.

In the method, the electrically connecting of the optical element may include: wire-bonding a first terminal and a first electrode pad such that the optical element is electrically connected with the first terminal formed on a top surface thereof; and wire-bonding a second terminal and a second electrode pad such that the optical element is electrically connected with the second terminal formed on a top surface thereof.

In the method, the electrically connecting of the optical element may include: wire-bonding a first terminal and a first electrode pad such that the optical element is electrically connected with the first terminal formed on a top surface thereof; and metal-bonding the circuit layer, in which a second terminal is integrated with a second electrode pad, such that the optical element is electrically connected with the second terminal formed on a top surface thereof.

### BRIEF DESCRIPTION OF THE DRAWINGS

The above and other objects, features and advantages of the present invention will be more clearly understood from the following detailed description taken in conjunction with the accompanying drawings, in which:

FIG. 1 is a sectional view showing a package substrate for optical elements according to a first embodiment of the present invention;

FIGS. 2A to 2F are sectional views showing a process of manufacturing the package substrate for optical elements of FIG. 1;

FIG. 3 is a sectional view showing a package substrate for optical elements according to a second embodiment of the present invention;

FIGS. 4A to 4F are sectional views showing a process of manufacturing the package substrate for optical elements of FIG. 3;

FIG. 5 is a sectional view showing a package substrate for optical elements according to a third embodiment of the present invention;

FIGS. 6A to 6G are sectional views showing a process of manufacturing the package substrate for optical elements of FIG. 5;

FIG. 7A is a sectional view showing a horizontal type package substrate for optical elements;

FIG. 7B is a sectional view showing a vertical type package substrate for optical elements;

FIG. 8A shows a bar type package substrate array for optical elements; and

FIG. 8B shows a plate type package substrate array for optical elements.

### DESCRIPTION OF THE PREFERRED EMBODIMENTS

The objects, features and advantages of the present invention will be more clearly understood from the following detailed description and preferred embodiments taken in conjunction with the accompanying drawings. Throughout the accompanying drawings, the same reference numerals are used to designate the same or similar components, and redundant descriptions thereof are omitted. Further, in the description of the present invention, when it is determined that the detailed description of the related art would obscure the gist of the present invention, the description thereof will be omitted.

Hereinafter, preferred embodiments of the present invention will be described in detail with reference to the attached drawings.

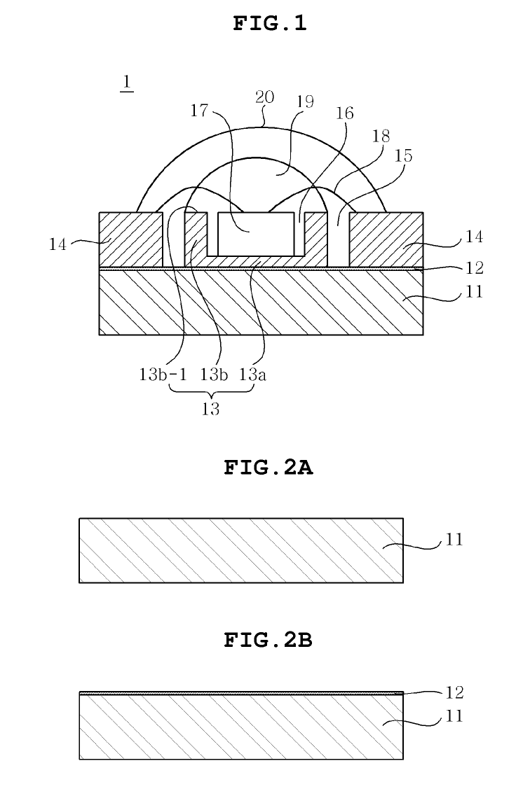

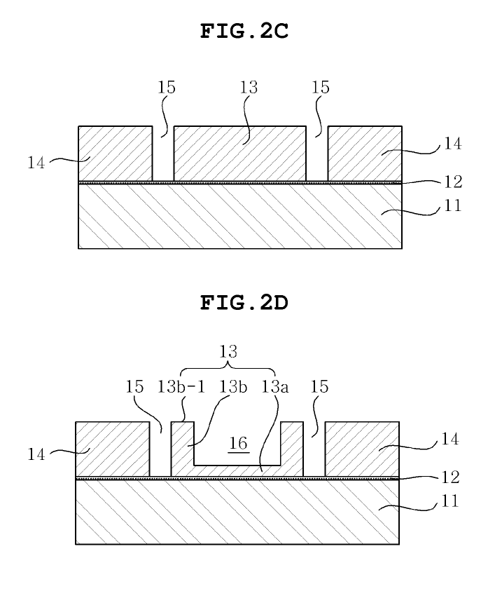

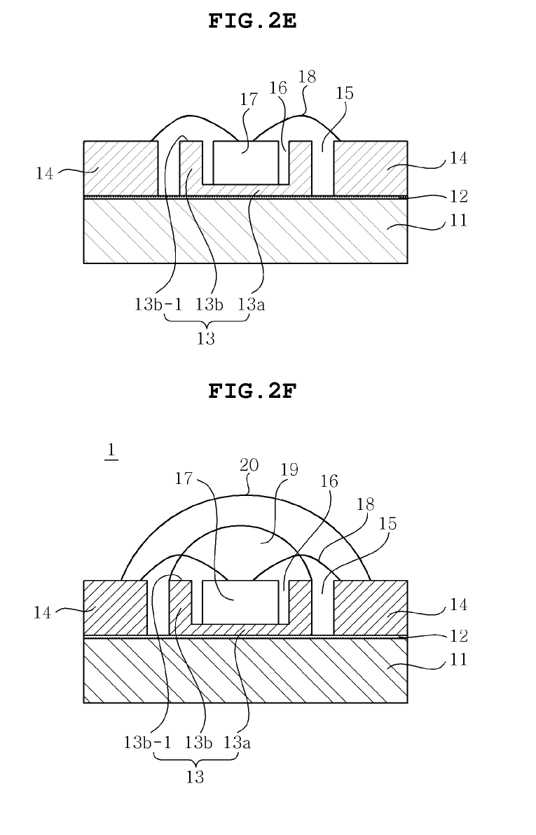

FIG. 1 is a sectional view showing a package substrate 1 for optical elements according to a first embodiment of the present invention, and FIGS. 2A to 2F are sectional views showing a process of manufacturing the package substrate 1 for optical elements of FIG. 1.

Hereinafter, a package substrate 1 for optical elements according to a first embodiment of the present invention and a method of manufacturing the package substrate 1 will be described with reference to FIG. 1 and FIGS. 2A to 2F.

As shown in FIG. 1, the package substrate 1 for optical elements according to a first embodiment of the present invention includes: a conductive substrate 11 including an insulation layer 12 formed thereon; a circuit layer 13 formed on the conductive substrate 11 and having a cavity space 16; electrode pads 14 which are formed on the conductive substrate 11 and which are spaced apart from the circuit layer 13 by predetermined intervals such that trenches 15 are formed between the circuit layer 13 and the electrode pads 14; an optical element 17 which is mounted in the cavity space 16 of the circuit layer 13 and which is electrically connected with the electrode pads 14; and a fluorescent resin layer which is formed on the circuit layer 13 and the optical element 17 to allow the optical element to uniformly emit light and which is formed by filling the cavity space 16 mounted with the optical element 17 with a resin material containing a fluorescent substance.

In order to manufacture this package substrate 1 for optical elements, as shown in FIG. 2A, first, a conductive substrate 11, which is to be used to manufacture the package substrate 1 for optical elements, is provided.

The conductive substrate 11 is a metallic substrate, and may be made of aluminum (Al), aluminum alloy (Al alloy), magnesium (Mg), magnesium alloy (Mg alloy), titanium (Ti), titanium alloy (Ti alloy), or the like.

In this case, the shape and size of the conductive substrate 11 are not particularly determined, and can be changed according to the processing ability of a production line and the density of a package structure. The conductive substrate 11 may have a thickness of about 0.1 mm in consideration of the reliability of products during and after a process.

Subsequently, in order to form circuit layers (for example 13 and 14) necessary for mounting the optical element 17 on the conductive substrate 11, as shown in FIG. 2B, an insulation layer 12 is formed on the surface of the conductive substrate 11 to insulate the conductive substrate 11. In FIG. 2B, the insulation layer 12 is formed on only the top surface of the conductive substrate 11, but may be formed on the entire surface thereof.

The insulation layer may be formed using an anodizing process, a plasma electrolyte oxidation (PEO) process, a dry oxidation process, a bonding process or the like.

Subsequently, this insulated conductive substrate 11 is plated with a conductor to form circuit layers having desired conductive patterns thereon. In this case, the circuit layers may include seed layers (not shown), and may be formed to have desired thickness.

Among the circuit layers formed in this way, as shown in FIG. 2C, there are a circuit layer 13 for mounting the optical element 17 and electrode pads 14 electrically connected with the optical element 17.

The circuit layer 13 and the electrode pads 14 according to the first embodiment of the present invention are formed by plating the insulated conductive substrate 11 with a conductor to such a thickness that the optical element is sufficiently buried. Here, the plating thickness is changed depending on the thickness of the optical element 17, and may be 35˜300 μm. Examples of the conductor used in the plating may include, but are not limited to, gold (Au), aluminum (Al), copper (Cu), and the like.

Observing the circuit layer 13 in detail with reference to FIG. 2D, the circuit layer 13 includes a lower part 13a on which the optical element 17 is placed, and side wall 13b which are integrated with the lower part 13a and which are spaced apart from the optical element 17 by predetermined intervals.

In order to form a cavity space 16 for mounting the optical element 17 in the circuit layer, the circuit layer 13, which is formed by plating the insulated conductive substrate 11 with a conductor to such a thickness that the optical element is sufficiently buried, is partially etched.

The cavity space 16 may be formed by etching the circuit layer 13 using a chemical etching method using an etchant or a mechanical forming method such as computerized numerical control (CNC) drilling or stamping using a mold.

At the time of etching the circuit layer 13, the circuit layer is etched by the thickness of the optical element 17 such that the optical element 17 is completely buried in the cavity space 16.

In other words, the top surface of the optical element 17 placed on the lower part 13a of the circuit layer 13 is flush with the top surface 13b-1 of the side wall 13b thereof.

Further, as shown in FIG. 2D, the electrode pads 14 are spaced apart from the circuit layer 13 by predetermined intervals, and thus trenches 15 are formed between the electrode pads 14 and the circuit layer 13.

Therefore, the circuit layer 13 is stepped by the trenches 15. For this reason, when a fluorescent resin material is applied onto the circuit layer 13 in order to form a fluorescent resin layer 19, the spreadability of the fluorescent resin material is decreased by the surface tension attributable to the step of the circuit layer 13, so that the formed fluorescent resin layer 19 is maintained in a dome shape.

Subsequently, as shown in FIG. 2E, the optical element 17 is mounted in the cavity space 16 of the circuit layer 13. Specifically, the optical element 17 is placed on the lower part 13a of the circuit layer 13.

Here, the optical element 17 may be a light emitting diode (LED). Subsequently, bonding is performed in order to electrically connect the optical element 17 with the electrode pads 14.

The bonding may be performed using wire bonding or metal boding.

The wire bonding is performed at the inside and outside of the cavity space 16. In the wire bonding, the optical element 17 is bonded with the electrode pads 14 using wire 18.

Examples of the wire 18 used in the wire bonding may include, but are not limited to, gold (Au) wire, aluminum (Al) wire, copper (Cu) wire, and the like.

The metal bonding is performed at the inside of the cavity space 16. That is, the metal bonding may be performed at the region at which the lower part 13a of the circuit layer 13 is brought into contact with the lower end of the optical element.

The metal bonding can be used to manufacture a vertical type package substrate for optical elements. In this case, one of the electrode pads 14, the one not being wire-bonded, is integrated with a part of the circuit layer 13.

After the wire bonding and metal bonding, as shown in FIG. 2F, the cavity space 16 mounted therein with the optical element 17 is filled with a resin material, and then a fluorescent resin layer 19 is formed thereon in a dome shape such that the optical element uniformly emits light.

Here, the fluorescent resin layer 19 may be made of a transparent resin material including a fluorescent substance having a specific color coordinate in order to allow the optical element 17 to uniformly emit light.

The above-mentioned package substrate 1 for optical elements may further include a lens 20 molded on the fluorescent resin layer 19 in order to hold the optical element 17 and to protect the optical element 17 and the wire bonding region.

The lens 20 may be fabricated in various sizes and shapes in consideration of the wide directivity angle characteristics by injection-molding, transfer-molding or dispensing-molding an epoxy molding compound (EMC), a silicon resin or an epoxy resin.

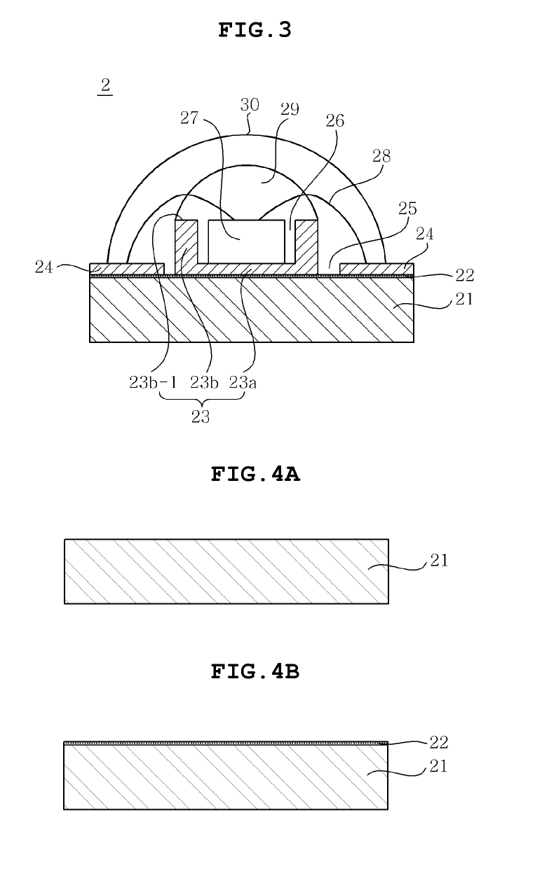

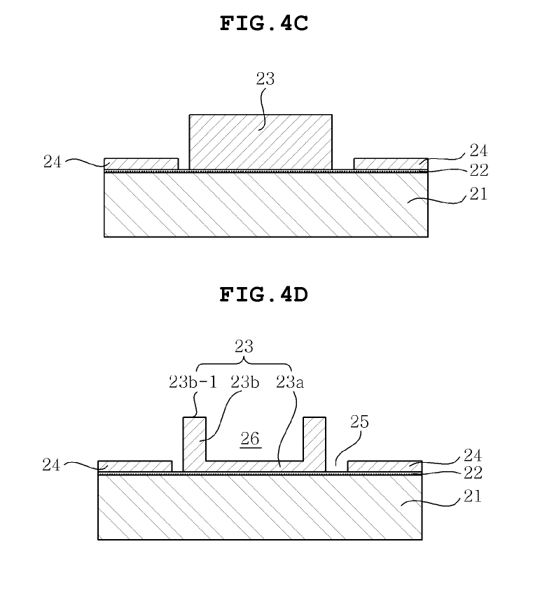

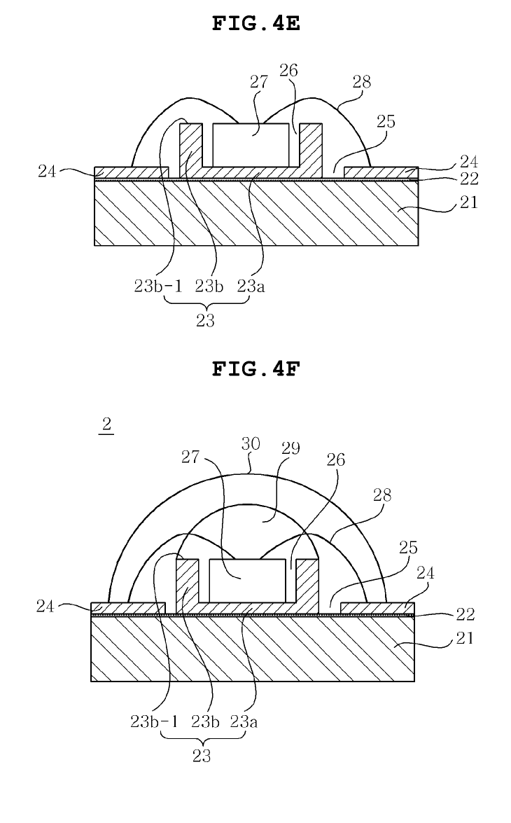

FIG. 3 is a sectional view showing a package substrate 2 for optical elements according to a second embodiment of the present invention, and FIGS. 4A to 4F are sectional views showing a process of manufacturing the package substrate 2 for optical elements of FIG. 3.

The package substrate 2 for optical elements according to a second embodiment of the present invention has the same structure as the package substrate 1 for optical elements of FIG. 1 according to a first embodiment of the present invention except for the thickness of electrode pads 24. Therefore, the package substrate 2 for optical elements according to a second embodiment of the present invention will be described based on the differences therebetween, and a detailed description of the same constituents and manufacturing process thereof will be omitted.

Referring to FIG. 4D, when circuit layers are formed on an insulated conductive substrate 21, the circuit layers may further be selectively plated with a conductor in order to form a circuit layer having desired thickness.

In other words, electrode pads 24 and a circuit layer 23 are formed in the same thickness, and then only the circuit layer 23, in which an optical element 27 is to be mounted, is further selectively plated with a conductor to such a thickness that the optical element 27 is sufficiently buried.

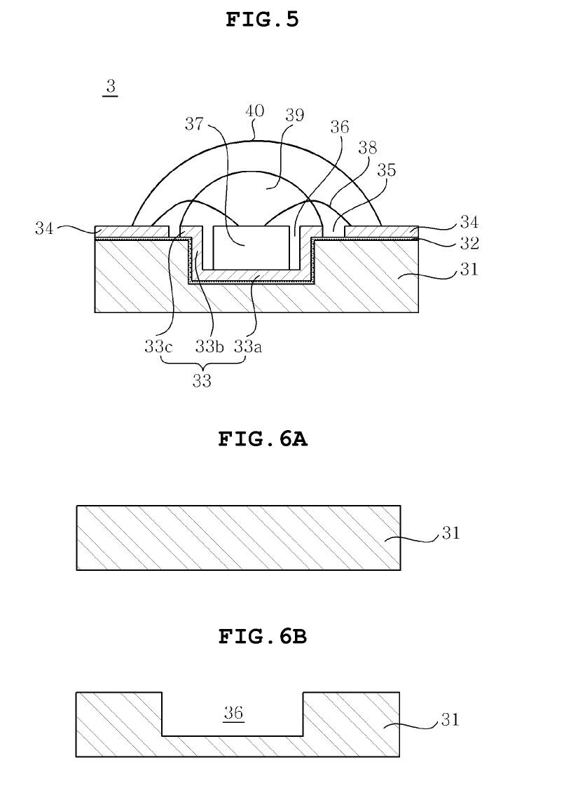

Meanwhile, the conductive substrate 11 may be provided therein with a cavity space identical to the cavity space 16 formed in the circuit layer 13. In this case, a package substrate for optical element, manufactured using this conductive substrate including the cavity space formed therein, is shown in FIG. 5.

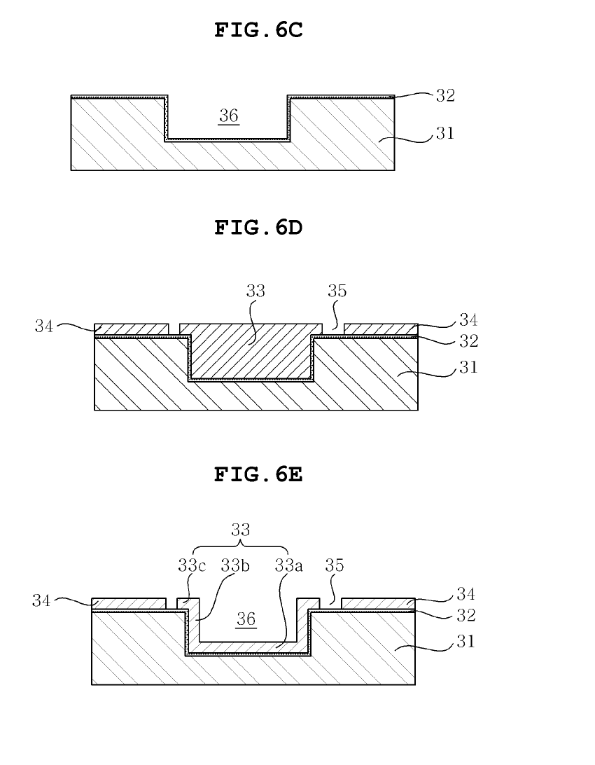

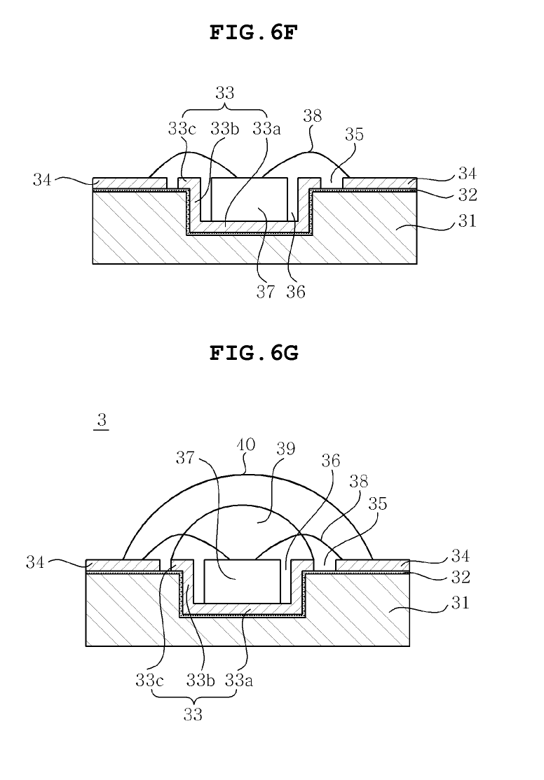

FIG. 5 is a sectional view showing a package substrate 3 for optical elements according to a third embodiment of the present invention, and FIGS. 6A to 6G are sectional views showing a process of manufacturing the package substrate 3 for optical elements of FIG. 5.

As shown in FIG. 5, the package substrate 3 for optical elements according to a third embodiment of the present invention has the same structure as the package substrate 2 for optical elements of FIG. 3 according to a second embodiment of the present invention, except that a circuit layer 33 having a cavity space 36 is inserted in a conductive substrate 31. Therefore, the package substrate 3 for optical elements according to a third embodiment of the present invention will be described based on the difference therebetween, and detailed description of the same constituents and manufacturing process thereof will be omitted.

Referring to FIG. 5, the package substrate 3 for optical elements according to a third embodiment of the present invention includes an insulated conductive substrate 31, a circuit layer 33, electrode pads 34, an optical element 37, and a fluorescent resin layer 39.

The package substrate 3 for optical elements according to this embodiment has a structure in which the circuit layer 33 is inserted in the conductive substrate 31. The circuit layer 33 includes a lower part 33a on which the optical element 37 is placed, side wall 33b which are integrated with the lower part 33a and which are spaced apart from the optical element 37 by predetermined intervals, and upper parts 33c which are integrated with the side wall 33b to cover the top surfaces of the side wall 33b.

The thickness of the upper parts 33c may be equal to or thicker than the thickness of the electrode pads 34 spaced apart from the circuit layer 33.

Hereinafter, a method of manufacturing the package substrate 3 for optical elements according to a third embodiment of the present invention will be described with reference to FIGS. 6A to 6G. First, a conductive substrate 31, which is to be used to manufacture the package substrate 3 for optical elements, is provided (refer to FIG. 6A).

Subsequently, as shown in FIG. 6B, a cavity space 36, in which an optical element 37 is to be mounted, is formed by etching the conductive substrate 31 using chemical etching or mechanical forming Subsequently, in order to form circuit layers (for example 33 and 34) on the conductive substrate 31 in desired conductive patterns, as shown in FIG. 6C, an insulation layer 32 is formed on the surface of the conductive substrate 31 to insulate the conductive substrate 31. Subsequently, as shown in 6D, a circuit layer 33 and electrode pads 34 are formed on the insulated conductive substrate 31 such that they are flush with each other by plating the conductive substrate 31 with a conductor. Subsequently, as shown in FIG. 6E, in order to form the cavity space 36 necessary for mounting the optical element 37 in the circuit layer 33, the circuit layer 33 is partially etched using chemical etching or mechanical forming. Subsequently, as shown in FIG. 6F, the optical element 37 is mounted in the cavity space 36, and then wire bonding and metal bonding are performed to electrically connect the optical element 37 with the electrode pad 34. Subsequently, as shown in FIG. 6G, a fluorescent resin layer 39 is formed by applying a resin material including a fluorescent substance using the same method as in the method of manufacturing a package substrate for optical elements according to the first or second embodiment of the present invention.

As described above, the top surfaces of the optical elements 17, 27 and 37 are flush with the top surfaces of the side wall 13b and 23b of the circuit layers 13 and 23 or the top surface of the upper part 33c of the circuit layer 33, respectively, and the fluorescent resin layers 19, 29 and 39 applied on the optical elements 17, 27 and 37 can be maintained in a dome shape because of the steps of the circuit layers 13, 23 and 33, respectively, so that the lengths of the optical paths through which light is transmitted from the optical elements 17, 27 and 37 to the resin materials (fluorescent substances) of the fluorescent resin layers 19, 29 and 39 are comparatively identical, and thus the optical elements 17, 27 and 37 can uniformly emit light.

Further, in the package substrates 1, 2 and 3 for optical elements according to the first, second and third embodiments of the present invention, since the circuit layer 13, 23 and 33 have metallic properties, they can reflect the light emitted from the optical elements 17, 27 and 37 mounted therein, and can easily radiate the heat generated from the optical elements 17, 27 and 37. In particular, the lower parts 13a, 23a and 33a of the circuit layers 13, 23 and 33 can become electrode pads which are later metal-bonded with the optical elements 17, 27 and 37.

That is, since the circuit layers 13, 23 and 33 can function as reflection units, radiation units and electrode pads, a package substrate for optical elements, having excellent light efficiency and radiation performance, can be manufactured.

Hitherto, for the convenience of explanation of the present invention, a single package substrate for optical elements was described. However, the package substrate of the present invention is not limited thereto, and may be variously fabricated depending on structure and use.

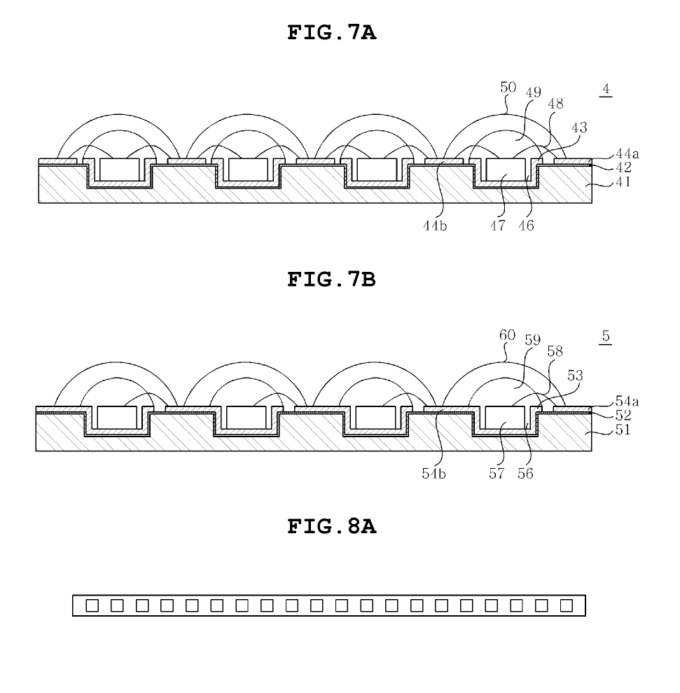

For example, according to the bonding type of the optical elements 17, 27 and 37, FIG. 7A shows a horizontal type package substrate for optical elements, and FIG. 7B shows a vertical type package substrate for optical elements.

As shown in FIG. 7A, in a horizontal type package substrate 4 for optical elements, all wirings for applying (+) and (−) signals to an optical element 47 are achieved by the wire bonding between electrode patterns 44a and 44b and the top surface of the optical element 47.

As shown in FIG. 7B, in a vertical package substrate 5 for optical elements, as wirings for applying (+) and (−) signals to an optical element 57, one wiring is achieved by the wire bonding between one (54a) of electrode patterns 54a and 54b and the top surface of the optical element 57, and the other wiring is achieved by the metal bonding between the bottom surface of the optical element 57 and the lower part of the circuit layer 53, which are brought into contact with each other.

In this case, a part of the circuit layer 53, which is metal-bonded with the bottom surface of the optical element 57, is integrated with the other (54b) of electrode patterns 54a and 54b.

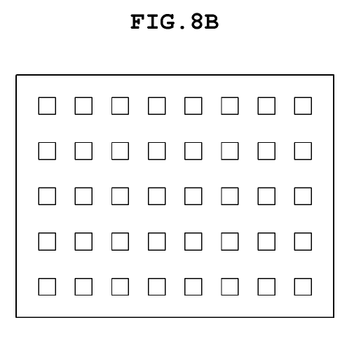

Further, various types of package substrate arrays for optical elements are shown according to use in FIGS. 8A and 8B.

FIG. 8A shows a bar type package substrate array for optical elements in which package substrates are serially arranged, and FIG. 8B shows a plate type package substrate array for optical elements in which package substrates are arranged in a matrix form.

As described above, according to a package substrate for optical elements and a method of manufacturing the same of the present invention, since a circuit layer mounted therein with an optical element is stepped, a fluorescent resin material can be easily applied, and uniform white light can be realized.

Further, according to the present invention, since the circuit layer mounted therein with an optical element is made of a metallic conductor, light efficiency and radiation performance can be improved.

Although the preferred embodiments of the present invention have been disclosed for illustrative purposes, those skilled in the art will appreciate that various modifications, additions and substitutions are possible, without departing from the scope and spirit of the invention as disclosed in the accompanying claims.

What is claimed is:

1. A package substrate for optical elements, comprising:
a conductive substrate including an insulation layer formed thereon;
a circuit layer which is formed on the conductive substrate 11 and has a cavity space therein;
electrode pads which are formed on the conductive substrate and which are spaced apart from the circuit layer by predetermined intervals such that trenches are formed between the circuit layer and the electrode pads;
an optical element which is mounted in the cavity space of the circuit layer and which is electrically connected with the electrode pads; and
a fluorescent resin layer which is formed on the circuit layer and the optical element to allow the optical element to uniformly emit light and which is formed by filling the cavity space mounted with the optical element with a resin material containing a fluorescent substance.

2. The package substrate for optical elements according to claim 1, further comprising a lens molded on the fluorescent resin layer in order to hold the optical element and to protect the optical element and a wire bonding region.

3. The package substrate for optical elements according to claim 1, wherein the conductive substrate is any one selected from among an aluminum (Al) substrate, an aluminum alloy (Al alloy) substrate, a magnesium (Mg) substrate, a magnesium alloy (Mg alloy) substrate, a titanium (Ti) substrate, and a titanium alloy (Ti alloy) substrate.

4. The package substrate for optical elements according to claim 1, wherein the conductive substrate has a thickness of 0.1 mm or more.

5. The package substrate for optical elements according to claim 1, wherein the circuit layer comprises:
a lower part on which the optical element is placed; and
side wall which are spaced apart from the optical element by predetermined intervals and which are integrated with the lower part.

6. The package substrate for optical elements according to claim 1, wherein a top surface of the optical element placed on the lower part of the circuit layer is flush with top surfaces of the side wall thereof.

7. The package substrate for optical elements according to claim 1, wherein the circuit layer is made of any one selected from among gold (Au), aluminum (Al) and copper (Cu).

8. The package substrate for optical elements according to claim 1, wherein the optical element includes first and second terminals formed on a top surface thereof,
the electrode pads include a first electrode pad electrically connected with the first terminal by wire bonding and a second electrode pad electrically connected with the second terminal by wire bonding, and
opposite polar signals are applied to the first and second terminals, respectively.

9. The package substrate for optical elements according to claim 1, wherein the optical element includes a first terminal formed on a top surface thereof and a second terminal formed on a bottom surface thereof,
the electrode pads include a first electrode pad electrically connected with the first terminal by wire bonding and a second electrode pad electrically connected with the second terminal by metal-bonding with the circuit layer, and
opposite polar signals are applied to the first and second terminals, respectively.

10. The package substrate for optical elements according to claim 9, wherein the second electrode pad is integrated with the circuit layer.

11. The package substrate for optical elements according to claim 1, wherein the optical element is a light emitting diode (LED).

12. The package substrate for optical elements according to claim 1, wherein the lower part and side wall of the circuit layer are inserted in the conductive substrate.

13. The package substrate for optical elements according to claim 12, wherein the circuit layer further comprises upper parts integrated with the side wall on the insulation layer.

14. A method of manufacturing a package substrate for optical elements, comprising:
providing a conductive substrate including an insulation layer formed thereon;
forming a circuit layer and electrode pads on the conductive substrate using a plating process;
forming a cavity space in the circuit layer including a lower part and a side wall; and
mounting an optical element in the cavity space and then applying a fluorescent resin layer thereon.

15. The method of manufacturing a package substrate for optical elements according to claim 14, wherein the providing of the conductive substrate comprises:
providing the conductive substrate; and
forming an insulation layer on the conductive substrate.

16. The method of manufacturing a package substrate for optical elements according to claim 14, further comprising: forming a cavity space in the conductive substrate after the providing of the conductive substrate.

17. The method of manufacturing a package substrate for optical elements according to claim 14, wherein the mounting of the optical element comprises:
placing the optical element on a lower part of the circuit layer;
electrically connecting the optical element; and
filling the cavity space with a resin material including a fluorescent substance to form a dome-shaped fluorescent resin layer on the optical element.

18. The method of manufacturing a package substrate for optical elements according to claim 17, wherein the electrically connecting of the optical element comprises:
wire-bonding a first terminal and a first electrode pad such that the optical element is electrically connected with the first terminal formed on a top surface thereof; and
wire-bonding a second terminal and a second electrode pad such that the optical element is electrically connected with the second terminal formed on a top surface thereof.

19. The method of manufacturing a package substrate for optical elements according to claim 17, wherein the electrically connecting of the optical element comprises:
wire-bonding a first terminal and a first electrode pad such that the optical element is electrically connected with the first terminal formed on a top surface thereof; and
metal-bonding the circuit layer, in which a second terminal is integrated with a second electrode pad, such that the optical element is electrically connected with the second terminal formed on a top surface thereof.
